(19) United States
(12) Patent Application Publication
(10) Pub. No.: US 2007/0004597 A1
(43) Pub. Date: Jan. 4, 2007

(54) Nb-Sn phase superconducting wire and precursor wire thereof

(75) Inventors: Yoshio Kubo, Tokyo (JP); Takanori Sone, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 11/156,581

(22) Filed: Jun. 21, 2005

(30) Foreign Application Priority Data
Jul. 20, 2004 (JP) 2004-211122

(51) Int. Cl. H01L 39/24

(52) U.S. Cl. 505/230

(57) ABSTRACT

The Nb-Sn phase superconducting wire 15 elongating in the longitudinal direction and having a cross section including a core part and a shell part surrounding of the core part. The wire 15 includes a core part made of only bronze 17 and a shell part including: a matrix made of bronze 17; and Nb₃Sn filaments 16 embedded in the bronze, wherein the Nb₃Sn filaments 16 are radially arranged and electromagnetically and radially coupled to one another in the radius direction of the wire 15 in the surrounding of the core part, and wherein the Nb₃Sn filaments 16 have larger diameters toward the outside, and the Nb₃Sn filaments 16 are kept at spacing so as to electromagnetically isolated from one another in the circumferential direction of the wire 15.

### BACKGROUND OF THE INVENTION

1. Field of the Invention

The invention relates to a Nb-Sn phase superconducting wire and a precursor wire thereof.

2. Description of the Related Art

As a Nb-Sn phase superconducting wire, those having a structure in which Nb₃Sn filaments are embedded as densely as possible in a bronze matrix in order to increase a critical current density (Jc), which is one of superconducting properties of a wire, as highly as possible have been developed (e.g. reference to Japanese Examined Patent Publication No. 61-16141 (page 1)).

Further, to lower the hysteresis loss (Qₕ), which is another electrical property of a wire, there have been developed those having a structure in which no Nb filament is allowed to exist in the region of the ε-phase bronze to be produced in the preliminary heat-treatment and also those having a structure in which the filament spacing in the region is so widened as to prevent Nb₃Sn to be produced after heat-treatment from contact (e.g. reference to Japanese Patent Laid-Open Publication No. 6-338228 (page 1)).

### SUMMARY OF THE INVENTION

However, the superconducting wire disclosed in the above-mentioned Japanese Examined Patent Publication No. 61-16141 (page 1) is so-called a high Jc type and a precursor of the Nb-Sn phase superconducting wire comprises Nb filaments arranged as densely as possible and has Jc about 1,500 A/mm² (a measured value in a magnetic field of 12 T and hereinafter, Jc in this specification is a value measured similarly in the magnetic field), however since the Nb₃Sn filaments are brought into contact with or electromagnetically coupled to one another during the heat-treatment for producing the superconducting layer, the Qₕ of the wire is increased to about 2,000 mJ/cm³ (a measured value showing the loss caused in the superconductor inside by altering the applied magnetic field in one cycle from +3 T to −3 T and hereinafter, Qₕ in this specification is a value measured similarly in the applied magnetic field alteration) or more and as a result, although there occurs no problem for d.c. use, there is a problem that a high hysteresis loss is caused in the case of pulsed current application and the stability of the superconducting coil is deteriorated by heat generation.

Further, the superconducting wire disclosed in the Japanese Patent Application Laid-Open No. 6-338228 (page 1) is so-called low hysteresis loss type and controllable for suppressing Qₕ as low as 200 mJ/cm³, however it is required to widen the spacing of Nb₃Sn filaments which in the region are easily brought into contact and/or keep a distance between the filament in the innermost layer and a Sn core at the production and therefore it becomes difficult to satisfy Jc≧1,000 A/mm².

The invention has been accomplished to solve the above-mentioned problems and aims to provide a wire having Jc so high for practical use and in which the increase of Qₕ is suppressed.

In accordance with one aspect of the present invention, there is a Nb-Sn phase superconducting wire elongating in the longitudinal direction and having a cross section including a core part and a shell part surrounding of the core part. The wire includes:

a core part made of only bronze; and

a shell part including:

a matrix made of bronze; and

a Nb₃Sn filaments embedded in the bronze, wherein the Nb₃Sn filaments are radially arranged and electromagnetically and radially bonded to one another in the radius direction of the wire in the surrounding of the core part, and wherein the Nb₃Sn filaments have larger diameters toward the outside, and the Nb₃Sn filaments are kept at spacing so as to electromagnetically isolated from one another in the circumferential direction of the wire.

The first Nb-Sn phase superconducting wire of the invention is one comprising Nb₃Sn filaments embedded in the bronze and characterized in that the core part is made of only bronze and that the Nb₃Sn filaments are radially arranged and electromagnetically and radially bonded to one another in the radius direction of the Nb-Sn phase superconducting wire in the surrounding of the core part; have larger diameters toward the outside; and are arranged at spacing so as to be electromagnetically isolated from one another in the circumferential direction of the Nb-Sn phase superconducting wire and the superconducting wire is provided with Jc high enough for practical use and the suppressed increase of Oₕ.

### BRIEF DESCRIPTION OF THE DRAWINGS

The present invention will become readily understood from the following description of preferred embodiments thereof made with reference to the accompanying drawings, in which like parts are designated by like reference numeral, and in which:

FIG. 1 is an explanatory view of a Nb-Sn phase superconducting wire of the embodiment 1;

FIG. 2 is an explanatory view of a precursor of a Nb-Sn phase superconducting wire of the embodiment 2;

FIG. 3 is an explanatory view of an oxygen-free copper disk relevant to the precursor of the Nb-Sn phase superconducting wire of the embodiment 2;

FIG. 4 is an explanatory view of a composite before the extrusion process relevant to the precursor of the Nb-Sn phase superconducting wire of the embodiment 2;

FIG. 5 is an explanatory view of a Nb-Sn phase superconducting wire of the embodiment 3;

FIG. 6 is an explanatory view of the Nb-based metal material arrangement relevant to a precursor of a Nb-Sn phase superconducting wire of the embodiment 5;

FIG. 7 is an explanatory view of the Nb-based metal material arrangement relevant to a precursor of a Nb-Sn phase superconducting wire of the embodiment 6; and

FIG. 8 is an explanatory view of the Nb-based metal material arrangement relevant to a precursor of a Nb-Sn phase superconducting wire of the embodiment 7.

### DESCRIPTION OF THE PREFERRED EMBODIMENTS

### Embodiment 1

With respect to a Nb-Sn phase superconducting wire produced by a conventional internal-tin process, if it is tried to obtain a high Jc, Qₕ increases and if it is tried to obtain a low Qₕ, Jc decreases.

Therefore, it has been difficult to satisfy both characteristics; Jc high enough for practical use and practically usable Qₕ value, which are Jc≧1,000 A/mm² and Qₕ≦800 mJ/cm².

This embodiment of the invention is to obtain a Nb-Sn phase superconducting wire satisfying both characteristics; Jc≧1,000 A/mm² and Qₕ≦800 mJ/cm²; by suppressing the increase of Qₕ which is caused by increasing Jc.

In a field of a magnet for nuclear fusion, a Nb₃Sn wire is required to have a high Jc value to make the magnet compact and Qₕ value not so high as to lessen the refrigerating load of the magnet and the superconducting wire of this embodiment is effectively usable for such a field.

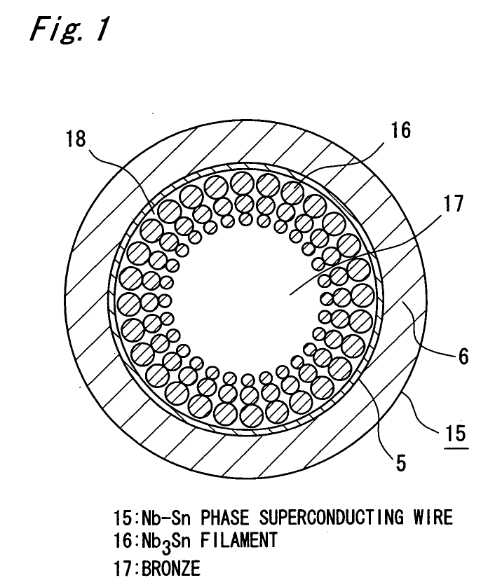

FIG. 1 is an explanatory view of a Nb-Sn phase superconducting wire 15 of the embodiment 1 of the invention which includes Nb₃Sn filaments 16 embedded in bronze and which is characterized in that the core part is made of only bronze 17 and that the Nb₃Sn filaments 16 are radially arranged in the radius direction of the Nb-Sn phase superconducting wire in the surrounding of the core part and brought into contact with one another radially and have larger diameters toward the outside.

Also, the Nb₃Sn filaments 16 are kept at spacing so as to electromagnetically isolated from one another in the circumferential direction of the Nb-Sn phase superconducting wire 15.

It is noted that the bronze 17 may exist in core part. Also, the bronze 17 may exist as matrix in shell part surrounding of the core part. Then, both the Nb₃Sn filaments 16 and bronze 17 as matrix can be regarded as shell part.

Further, as shown in FIG. 1, the filaments are surrounded with a barrier material 5 represented with Nb or Ta and a stabilizing material 6 such as oxygen-free copper is disposed in the outside of the barrier material 5.

As described in the following embodiments, the bronze 17 in the core part is a low Sn concentration bronze containing Sn in a lower content than that in the bronze which is once produced during the heat-treatment in the case of production of a superconducting wire from a precursor of a Nb-Sn phase superconducting wire by the heat-treatment in internal-tin process.

Further, the same figure shows the case the Nb₃Sn filaments arranged in the radially in the radius direction are in contact with one another and it is more desirable that the filaments are arranged more densely as to have the physical contact or electromagnetic coupling to each other at spacing of narrower than 0.4 μm and dense and radial arrangement of the filaments in the radial direction makes the spacing of the filaments in the circumferential direction wider than those in conventional arrangement. In other words, bonding only the filaments in the radius direction makes it possible to keep Qₕ equal to 800 mJ/cm³ or lower and accordingly the filaments can more densely be arranged.

The electromagnetic coupling means that superconducting electrons coming out to the circumference of the Nb₃Sn filaments are mutually overlaid on superconducting electrons coming out from the neighboring Nb₃Sn filaments and the isolated filaments behave electromagnetically as if they are one bonded filament and the electromagnetic isolation means that those coming-out superconducting electrons are not mutually interfered.

As shown in FIG. 1, in the case the Nb₃Sn filaments are concentrically arranged in a plurality of layers in the surrounding of the bronze 17 in the center of the Nb₃Sn superconducting wire, increase of the diameter of the Nb₃Sn filaments more in the outer side in such a manner as to satisfy D₁/L₁≦D₂/L₂≦D₂/L₃≦D₄/L₄ . . . wherein D_{N} denotes the diameter of the Nb₃Sn filaments in N^{th} layer from the innermost layers and L_{N} denotes the distance from the center of the Nb₃Sn filaments in the N^{th} layer to the center of the Nb₃Sn superconducting wire results in the efficient improvement of Jc.

### Embodiment 2

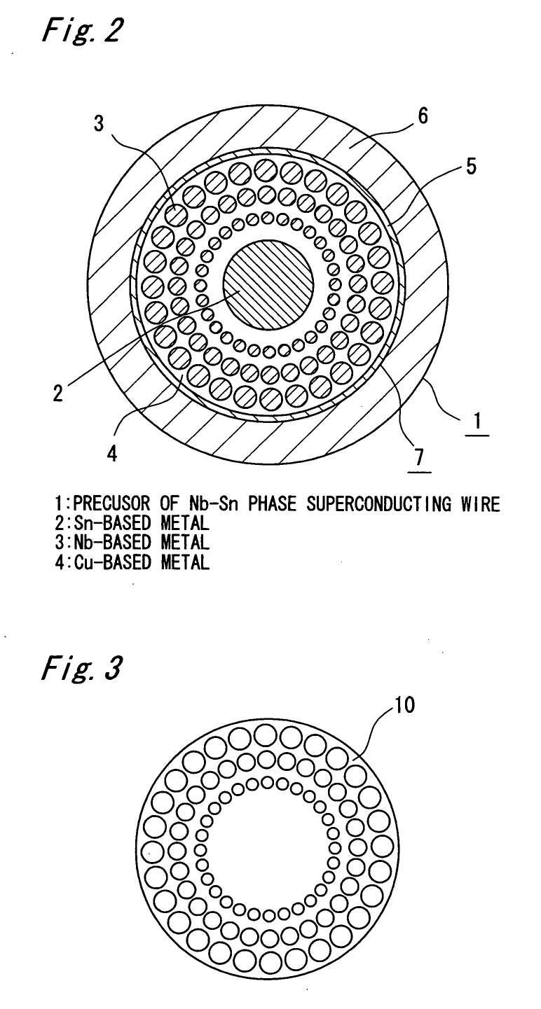

FIG. 2 is an explanatory drawing of a precursor of a Nb-Sn phase superconducting wire in the embodiment 2 of the invention and the precursor 1 of the Nb-Sn phase superconducting wire is composed by installing a Sn-based metal material 2 in the core part, arranging a plurality of layers of a Nb-based metal material 3 separately and concentrically in the surrounding of the Sn-based metal material 2, and so embedding them in a Cu-based metal material 4 as to be a superconducting wire by heat-treatment. A composite of the Sn-based metal material 2, Nb-based metal material 3 to be superconducting by heat-treatment, and Cu-based metal material 4 is called as a basic module 7. The basic module 7 is surrounded with a barrier material 5 represented with Nb or Ta and a stabilizing material 6 such as oxygen-free copper is installed in the outside of the barrier material 5. It is noted that the Cu-based metal material 4 may be referred to as matrix. Then, both the Nb-based metal material 3 and Cu-based metal material 4 can be regarded as shell part surrounding of the core part.

The Nb-based metal material of the precursor is arranged so as to form electromagnetic coupling in the material itself when it becomes superconductor by heat-treatment and the arrangement is carried out in such a manner as to satisfy sᵣ<0.07×(d_{N}+d_{N+1})+0.4 and Sₜ≧0.14×d_{N}+0.9 wherein d_{N} (μm) and d_{N+1} (μm) denote the diameter in the N^{th} layer and (N+1)^{th} layer from the innermost layer in the radius direction of the precursor, sᵣ (μm) denotes the spacing of the Nb-based metal material between the N^{th} layer and (N+1)^{th} layer from the innermost layer, and sₜ (μm) the spacing of the Nb-based metal material in the Nth layer in the circumferential direction.

The first term of the inequalities relevant to Sᵣ and sₜ expresses the quantity of the increase of the filament diameter due to following heat-treatment and the second term of the inequalities expresses the quantity of the decrease of the filament spacing due to following the decrease of the bronze, which is the matrix, because of the mutual diffusion of Cu/Sn.

With respect to the superconducting wire in the embodiment 1, to effectively increase the diameter of the filaments more in the outer side as described above, in the precursor in this embodiment, the Nb-based metal material is so arranged in the respective layers as to satisfy d₁/l₁≦d₂/l₂≦d₃/l₃ ≦d₄/l₄ . . . wherein d_{N} denotes the diameter of the Nb-based metal material in N^{th} layer from the innermost layers and IN denotes the distance from the center of the Nb-based metal material in the N^{th} layer to the center of the precursor.

Practically, the filament diameter/spacing in the innermost layer, the second layer, and the outermost layer is adjusted as 2.7/1.3 μm, 3.2/1.6 μm, and 3.8/1.9 μm, respectively, and the filament spacing between the innermost layer and the second layer and between the second layer and the outermost layer are adjusted as 0.4 μm and 0.5 μm, respectively.

The precursor 1 of the Nb-Sn phase superconducting wire in this embodiment may be, for example, obtained as follows.

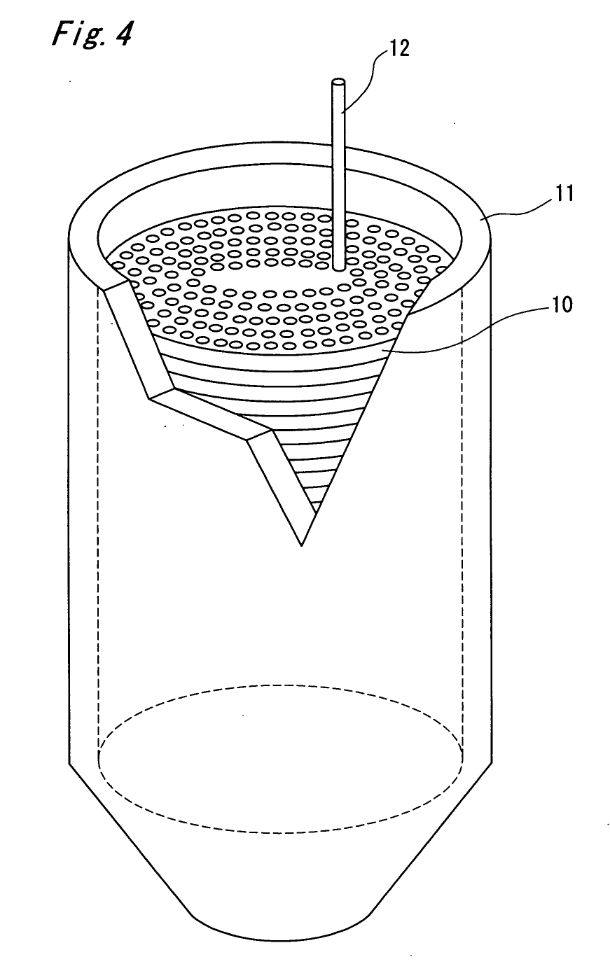

As shown in FIG. 3, each 28 holes with diameters 10.6 mm, 12.6 mm, and 14.9 mm are formed radially from the inner layer side in an oxygen-free copper disk 10 with a diameter of 229 mm and a thickness of 20 mm by a NC drilling machine. As shown in FIG. 4., thirty disks obtained in such a manner are disposed in an oxygen-free copper container 11 with an outer diameter of 250 mm and an inner diameter of 230 mm in a manner that the hole positions are conformed one another and Nb rods 12 with diameters of 10.5 mm, 12.5 mm, and 14.8 mm, respectively and a length of 600 mm are inserted into the holes of the group of the disks and the container is sealed by electron beam welding in vacuum evacuation condition to produce a composite.

Next, the composite is hydroisostatically pressed (HIP) and then hot-extruded to obtain a column of a Nb/Cu composite. The excess Cu in the outer circumference of the composite is cut off and the core part is drilled and a Sn rod is inserted therein and the resulting composite is wire-drawn to obtain a composite wire to be a basic module. The module is inserted into a Ta pipe, which is a Sn diffusion barrier material and further covered with a Cu pipe for stabilization to obtain a secondly assembled wire and then the wire is drawn to a wire diameter of 0.5 mm to obtain a precursor of Nb-Sn phase superconducting wire.

Next, the above-mentioned precursor of the superconducting wire is heated at 600 to 750° C. for 100 to 300 hours to form a Nb₃Sn superconductor in the Nb-based metal filaments.

It is confirmed that filaments in the 1st to 3rd layers radially arranged in the radius direction are bonded to one another by the heat-treatment by observation of a cross-section of the obtained Nb-Sn phase superconducting wire with an optical microscope. The reason for the alteration of the filament diameter and spacing before and after the reaction is that when Nb₃Sn compound is produced, the area of the Nb₃Sn filaments increases by about 30% and bronze, which is the matrix, decreases due to Cu/Sn mutual diffusion.

Jc and Qₕ of the above-mentioned Nb-Sn phase superconducting wire are found to be 1,057 A/mm² and 700 mJ/cm³, respectively, by measurement in liquid helium to confirm that the superconducting wire in this embodiment satisfies both Jc≧1,000 A/mm² and Qₕ≦800 mJ/cm³.

Additionally, as the constitution of the precursor, the precursor obtained by disposing only one basic module in the barrier material is exemplified, however a large number of basic modules obtained in such a manner may be disposed in the barrier material.

Also, in this embodiment, the precursor of the superconducting wire comprising the stabilizing material represented with Cu and the barrier material represented with Ta or Nb is exemplified for the explanation, the precursor may have a constitution without comprising the stabilizing material or the diffusion barrier material and even a precursor with such a constitution may provide the same effects as those in this embodiment.

Further, as a superconducting wire and its precursor in this embodiment, there are many superconducting wire which contain a small amount of Ti, Ta, Ga, In, Mn or the like in addition to Nb₃Sn exemplified in the embodiment and the invention also includes these materials.

### Embodiment 3

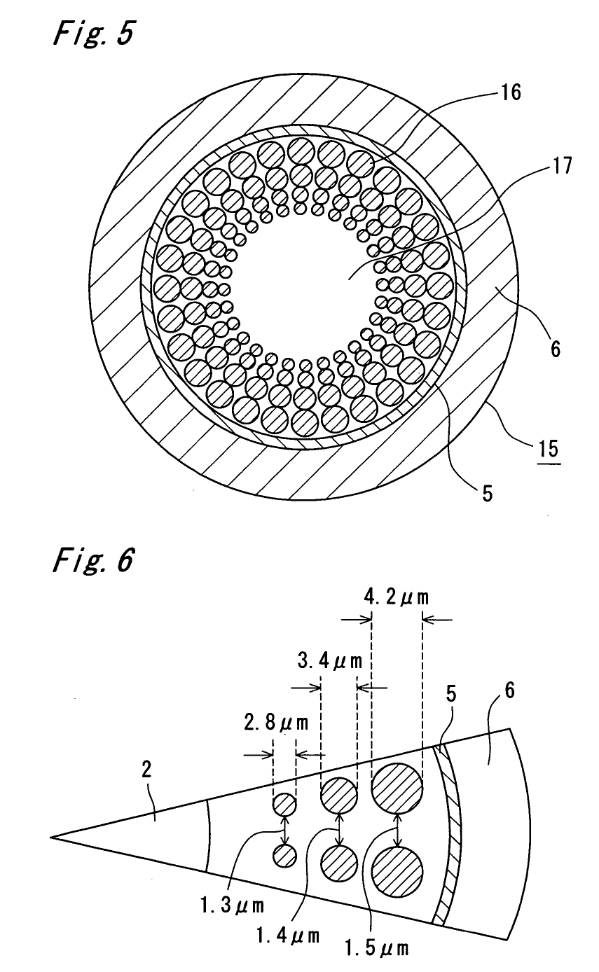

FIG. 5 is an explanatory drawing of a Nb-Sn phase superconducting wire in the embodiment 3 of the invention and it can be produced in the same manner as the Nb-Sn phase superconducting wire in the embodiment 2, except that the number of the layers of the Nb₃Sn filaments is changed to 4 and because 4 layer-structure of the Nb₃Sn filaments is employed, 28 Nb rods with diameter of 8.8 mm and length of 600 mm are added as the Nb-based metal material in the further inner side of the innermost layer of the precursor in the embodiment 2.

It is found that the filament diameter/spacing of the innermost layer, the second layer, the third layer, and the outermost layer is 2.6/0.5 μm, 3.1/0.6 μm, 3.6/0.7 μm, and 4.3/0.9 μm, respectively, and the filaments are brought into contact with one another between the innermost layer and the second layer, between the second layer and the third layer, between the third layer and the outermost layer by the cross-sectional observation of the superconducting wire obtained in the above-mentioned manner.

Jc and Qₕ of the superconducting wire are found to be 1,100 A/mm² and 790 mJ/cm³, respectively, by measurement in liquid helium to confirm that the superconducting wire in this embodiment has the same effects as those in the embodiment 2.

### Embodiment 4

With respect to the Nb-Sn phase superconducting wire in this embodiment 4 of the invention, the number of the Nb₃Sn filaments is increased from 28 to 29 in the embodiment 2 so that the Nb₃Sn filaments are arranged more densely than the embodiment 2 but not so high density as to form electromagnetic coupling among Nb₃Sn filaments in the circumferential direction and the Nb₃Sn filament diameter/spacing in the innermost layer are changed to be 3.1/0.4 μm.

That is, the precursor relevant to this embodiment is produced in the same manner as the embodiment 2, except that the filament diameter/spacing of Nb-based metal material is adjusted to be 2.7/1.2 μm, 3.2/1.4 μm, and 3.8/1.7 μm in the innermost layer, the second layer, and the outermost layer, respectively.

The precursor is heated at 600 to 750° C. for 100 to 300 hours to form Nb₃Sn superconductor in the Nb filament parts. Jc and Qₕ of the Nb-Sn phase superconducting wire in this embodiment obtained in the above-mentioned manner are found to be 1,094 A/mm² and 710 mJ/cm³, respectively, by measurement in liquid helium.

### Comparative Example 1

With respect to a superconducting wire of this comparative example, the Nb₃Sn filaments are arranged in the same manner as the embodiment 4, except that the spacing of the filaments are changed to be 0.3 μm, 0.4 μm, and 0.5 μm in the circumferential direction in the innermost layer, the second layer, and the outermost layer, respectively, and in production of a precursor, the wire-drawing of the secondly assembled wire is carried out to change a wire diameter from 0.5 mm to 0.357 mm, which is a wire diameter in the embodiment 4, to obtain a precursor of the Nb-Sn phase superconducting wire.

The precursor obtained in the above-mentioned manner is heated at 600 to 750° C. for 100 to 300 hours to form Nb₃Sn superconductor in the Nb filament parts. Jc and Qₕ of the obtained Nb-Sn phase superconducting wire are found to be 1,133 A/mm² and 2,200 mJ/cm³, respectively, by measurement in liquid helium. The value of Qₕ=2,200 mJ/cm³ is a value implying that the filaments in the first layer are electromagnetically coupled.

From the results in the embodiment 4 and the comparative example 1, it is found that if the spacing of the Nb₃Sn filaments in the innermost layer are narrower than 0.4 μm, Qₕ is sharply increased owing to the electromagnetic coupling. On the other hand, if it is 0.8 μm or wider, Jc is decreased significantly and accordingly, it is confirmed that Qₕ≦800 mJ/cm³ is achieved by adjusting the filament spacing in the circumferential direction to be not narrower than 0.4 μm and narrower than 0.8 μm.

### Embodiment 5

In this embodiment, to obtain a higher Jc than that of the Nb-Sn phase superconducting wire (the Nb₃Sn filament spacing in the innermost layer is 0.6 μm) produced in the embodiment 2, a precursor is produced by setting the diameter/spacing of the Nb-based metal filaments as follows so as to adjust the Nb₃Sn filament spacing to be 0.5 μm in the innermost layer, the second layer, and the outermost layer after heat-treatment.

FIG. 6 is an explanatory drawing of the arranged state for the Nb-based metal material corresponding the precursor of the Nb-Sn phase superconducting wire in the embodiment 5 of the invention and the Nb-based metal filament diameter/spacing in the innermost layer, the second layer, and the outermost layer, respectively, is adjusted to be 2.8/1.3 μm, 3.4/1.4 μm, and 4.2/1.5 μm.

The precursor is heated at 600 to 750° C. for 100 to 300 hours to form Nb₃Sn superconductor in the Nb filament parts. It is confirmed by cross-sectional observation of the wire that the Nb₃Sn filaments are bonded in the radius direction and the diameter/spacing of the filaments in the innermost layer, second layer, and outermost layer is 3.1/0.5 μm, 3.9/0.5 μm, and 4.8/0.5 μm, respectively.

Jc and Qₕ of the obtained Nb-Sn phase superconducting wire are found to be 1,215 A/mm² and 750 mJ/cm³, respectively, by measurement in liquid helium. The Qₕ value implies that the filaments in the circumferential direction are not coupled electromagnetically.

Since the Nb-based metal filament diameter/spacing is 2.7/1.3 μm, 3.2/1.6 μm, and 3.8/1.9 μm, respectively, in the innermost layer, second layer, and outermost layer of the precursor of the Nb-Sn phase superconducting wire in the embodiment 2 and the properties of Jc and Qₕ are Jc=1,057 A/mm² and Qₕ=700 mJ/cm³, respectively, it is confirmed that Jc of the superconducting wire in this embodiment is increased more than that in the embodiment 2 by increasing the filament diameter and thus arranging the filaments more densely to the extent that the electromagnetic coupling in the circumferential direction is not formed.

### Embodiment 6

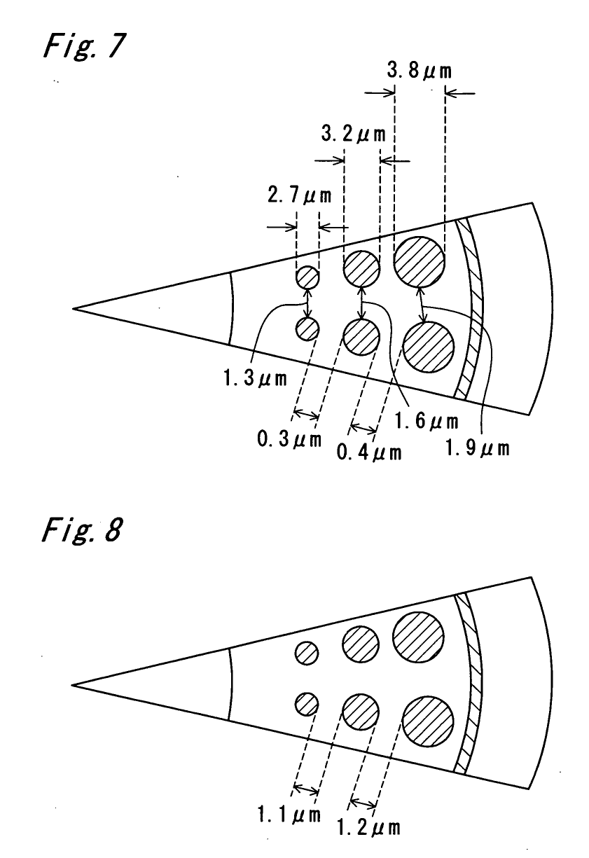

FIG. 7 is an explanatory drawing of a precursor of a Nb-Sn phase superconducting wire in the embodiment 6 of the invention and to obtain a higher Jc than that of the Nb-Sn phase superconducting wire in the embodiment 2, the precursor is produced in such a manner that, with the Nb-based metal filaments of the precursor in this embodiment, the spacing in the circumferential direction in the respective layers are set as same as those in the embodiment 2 and the spacing of the Nb-based metal filaments between the innermost layer and the second layer and between the second layer and the outermost layer are set to be 0.3 μm and 0.4 μm, respectively, narrower than those in the embodiment 2.

The precursor is heated at 600 to 750° C. for 100 to 300 hours to form Nb₃Sn superconductor in the Nb filaments. It is confirmed by cross-sectional observation of the wire that the Nb₃Sn filaments are bonded in the radius direction and the diameter/spacing of the filaments in the innermost layer, second layer, and outermost layer is 3.1/0.6 μm, 3.6/0.7 μm, and 4.3/0.9 μm (the diameter/spacing of the filaments in the innermost layer, second layer, and outermost layer is 3.1/0.6 μm, 3.6/0.7 μm, and 4.3/0.9 μm, respectively, in the embodiment 2).

Jc and Qₕ of the obtained Nb-Sn phase superconducting wire are found to be 1,105 A/mm² and 780 mJ/cm³, respectively, by measurement in liquid helium. The Qₕ value, 780 mJ/cm³, implies that the filaments in the circumferential direction are not coupled electromagnetically.

On the other hand, the spacing of the Nb-based metal material filament between the innermost layer and the second layer and between the second layer and the outermost layer of the precursor of the Nb-Sn phase superconducting wire in the embodiment 2 are 0.4 μm and 0.5 μm, respectively and Jc and Qₕ are 1,057 A/mm² and 700 mJ/cm³, respectively, and accordingly it is confirmed that Jc is further more increased than that in the embodiment 2 owing to the densified arrangement of the Nb₃Sn filaments in the first to the third layers bonded radially in the superconducting wire in this embodiment.

### Embodiment 7

With respect to the Nb-Sn phase superconducting wire in this embodiment, the filaments radially arranged in the first, second, and third layers are not brought into contact with one another but arranged so densely as to form electromagnetic coupling.

FIG. 8 is an explanatory drawing of the arranged state for the Nb-based metal material relevant to the precursor of the Nb-Sn phase superconducting wire in the embodiment 7 and the precursor is produced in the same manner as the embodiment 2, except that the spacing of the Nb-based metal material filament between the innermost layer and the second layer and between the second layer and the outermost layer are set to be 1.1 μm and 1.2 μm, respectively and the precursor is heated to 600 to 750° C. for 100 to 300 hours to produce Nb₃Sn superconductor in the Nb-based metal filament part.

It is found by the cross-sectional observation of the Nb-Sn phase superconducting wire that the Nb₃Sn filaments have a spacing of 0.3 μm each between the innermost layer and the second layer and between the second layer and the outermost layer in the radius direction and thus are not brought into contact with one another and that the Nb₃Sn filaments are so densely arranged as to form electromagnetic coupling. Also, the filament diameter/spacing is 3.1/0.6 μm, 3.6/0.7 μm, and 4.3/0.9 μm, respectively in the innermost layer, the second layer, and the outermost layer.

Jc and Oₕ of the obtained Nb-Sn phase superconducting wire are found to be 1,000 A/mm² and 670 mJ/cm³, respectively, by measurement in liquid helium.

In this embodiment, it is also confirmed that since the Nb₃Sn filaments arranged radially in the radius direction are not brought into contact with one another, the extent of electromagnetic coupling owing to the coming out effect of the superconducting electrons is narrowed and therefore the Qₕ is more effectively decreased.

Although the present invention has been described in connection with the preferred embodiments thereof with reference to the accompanying drawings, it is to be noted that various changes and modifications are apparent to those skilled in the art. Such changes and modifications are to be understood as included within the scope of the present invention as defined by the appended claims, unless they depart therefrom.

What is claimed is:

1. A Nb-Sn phase superconducting wire elongating in the longitudinal direction and having a cross section including a core part and a shell part surrounding of the core part, the wire comprising:
a core part made of only bronze; and
a shell part including:
a matrix made of bronze; and
Nb₃Sn filaments embedded in the bronze, wherein the Nb₃Sn filaments are radially arranged and electromagnetically and radially coupled to one another in the radius direction of the wire in the surrounding of the core part, and wherein the Nb₃Sn filaments have larger diameters toward the outside, and the Nb₃Sn filaments are kept at spacing so as to electromagnetically isolated from one another in the circumferential direction of the wire.

2. The Nb-Sn phase superconducting wire according to claim 1, wherein the Nb₃Sn filaments arranged radially in the radius direction are brought into contact with one another.

3. The Nb-Sn phase superconducting wire according to claim 1, wherein the Nb₃Sn filaments arranged radially in the radius direction are arranged at spacing of narrower than 0.4 μm.

4. The Nb-Sn phase superconducting wire according to claim 1, wherein the spacing of the Nb₃Sn filaments in the circumferential direction of the wire are not narrower than 0.4 μm and narrower than 0.8 μm.

5. The Nb-Sn phase superconducting wire according to claim 1, wherein the Nb₃Sn filaments are concentrically arranged in a plurality of layers in the surrounding of the bronze in the core part of the wire and satisfies D₁/L₁≦D₂/L₂≦D₃/L₃≦D₄/L₄ . . . , wherein D_{N} denotes the diameter of the Nb₃Sn filaments in N^{th} layer from the innermost layers and L_{N} denotes the distance from the center of the Nb₃Sn filaments in the N^{th} layer to the center of the wire.

6. A precursor of a Nb-Sn phase superconducting wire, the precursor being heated to produce the superconducting wire, the precursor elongating in the longitudinal direction and having a cross section including a core part and a shell part surrounding of the core part, the precursor comprising:
a core part made of only Sn-based material, the Sn-based metal material elongating in the longitudinal direction; and
a shell part including:
a matrix made of Cu-based metal material; and
a Nb-based metal material embedded in the Cu-based metal material, wherein the Nb-based metal material is arranged radially in the surrounding of the core part and at spacing so as to form electromagnetic coupling after the heat-treatment, and the Nb-based metal material has a wider diameter toward the outer side and in the circumferential direction of the precursor, wherein the Nb-based metal material is arranged at spacing so as to be electromagnetically isolated after the heat-treatment, and the Nb-based metal material elongates in the longitudinal direction.

7. The precursor of a Nb-Sn phase superconducting wire according to claim 6, wherein, in the radius direction of the precursor, the Nb-based metal material is arranged so as to make the Nb₃Sn compound have contact with itself at the time of production by the heat-treatment.

8. The precursor of a Nb-Sn phase superconducting wire according to claim 6, wherein in the radius direction of the precursor, the Nb-based metal material is arranged so as to keep the spacing of the Nb₃Sn compound to be narrower than 0.4 μm at the time of production by the heat-treatment.

9. The precursor of a Nb-Sn phase superconducting wire according to claim 6, wherein the Nb-based metal material is embedded in a plurality of layers concentrically in the surrounding of the Sn-based metal material and arranged so as to satisfy Sᵣ<0.07×(d_{N}+d_{N+1})+0.4, wherein Sᵣ (μm) denotes the spacing of the Nb-based metal material between the N^{th} layer and (N+1)^{th} layer from the innermost layer and d_{N} (μm) and d_{N+1} (μm) denote the diameter of the Nb-based metal material in the N^{th} layer and (N+1)^{th} layer from the innermost layer.

10. The precursor of a Nb-Sn phase superconducting wire according to claim 9, wherein the precursor satisfying sₜ≧0.14×d+0.9, wherein sₜ (μm) denotes the spacing in the circumferential direction of the Nb-based metal material and d (μm) denotes the diameter of the Nb-based metal material.

11. The precursor of a Nb-Sn phase superconducting wire according to claim 9, wherein the precursor satisfying d₁/l₁≦d₂/l₂≦d₃/l₃≦d₄/l₄ . . . , in the respective layers of Nb-base metal material, wherein d_{N} denotes the diameter of the Nb-based metal material in N^{th} layer from the innermost layers and l_{N} denotes the distance from the center of the Nb-based metal material in the N^{th} layer to the center of the precursor.
